(19) United States
(12) Patent Application Publication
(10) Pub. No.: US 2016/0260736 A1
(43) Pub. Date: Sep. 8, 2016

(54) SEMICONDUCTOR DEVICE AND METHOD FOR MANUFACTURING THE SAME

(71) Applicant: Kabushiki Kaisha Toshiba, Minato-ku (JP)

(72) Inventors: Kotaro FUJII, Yokkaichi (JP); Hideaki AOCHI, Yokkaichi (JP)

(73) Assignee: Kabushiki Kaisha Toshiba, Minato-ku (JP)

(21) Appl. No.: 14/821,921

(22) Filed: Aug. 10, 2015

Related U.S. Application Data
(60) Provisional application No. 62/127,669, filed on Mar. 3, 2015.

(51) Int. Cl. H01L 27/115

(52) U.S. Cl. CPC H01L 27/11582; H01L 27/11568

(57) ABSTRACT

According to one embodiment, the semiconductor film includes a first semiconductor part, a second semiconductor part, and a third semiconductor part. The first semiconductor part extends in the stacked body in a stacking direction of the stacked body. The second semiconductor part extends in the stacked body in the stacking direction and a first direction crossing the stacking direction. The third semiconductor part extends in the underlayer in a second direction connecting the first semiconductor part and the second semiconductor part. The first semiconductor part, the second semiconductor part and the third semiconductor part are made of a same material and are continuous with each other. The first metal layer is in contact with a side surface of the second semiconductor part.

### CROSS-REFERENCE TO RELATED APPLICATION

This application is based upon and claims the benefit of priority from U.S. Provisional Patent Application No. 62/127,669, filed on Mar. 3, 2015; the entire contents of which are incorporated herein by reference.

### FIELD

Embodiments described herein relate generally to a semiconductor device and a method for manufacturing a semiconductor device.

### BACKGROUND

A memory device of a three-dimensional structure is proposed. The memory device includes a stacked body, a charge storage film, and a semiconductor film. A plurality of electrode layers are stacked in the stacked body. The charge storage film and the semiconductor film extend in a stacking direction of the stacked body.

The semiconductor film functions as a channel, and an end of the semiconductor film is connected to a metal layer. A contact resistance between the semiconductor film and the metal layer is desired to be low.

### BRIEF DESCRIPTION OF THE DRAWINGS

FIG. 1 is a schematic perspective view of a memory cell array of a semiconductor device of an embodiment;

FIG. 2 is a schematic plan view of the memory cell array of the semiconductor device of the embodiment;

FIG. 3 is a schematic sectional view of a part of the memory cell array of the semiconductor device of the embodiment;

FIG. 4 is a schematic sectional view of a memory cell of the semiconductor device of the embodiment;

FIGS. 5A to 11 are schematic sectional views showing a method for manufacturing the semiconductor device of the embodiment;

FIG. 12 is a schematic sectional view of a part of the memory cell array of the semiconductor device of the embodiment;

FIGS. 13A and 13B are schematic sectional views showing a method for manufacturing the semiconductor device of the embodiment; and

FIG. 14 is a schematic sectional view of a part of the memory cell array of the semiconductor device of the embodiment.

### DETAILED DESCRIPTION

According to one embodiment, a semiconductor device includes an underlayer, a stacked body, a semiconductor film, a charge storage film, and a first metal layer. The stacked body is provided on the underlayer and includes a plurality of electrode layers stacked with insulators between the electrode layers. The semiconductor film includes a first semiconductor part, a second semiconductor part, and a third semiconductor part. The first semiconductor part extends in the stacked body in a stacking direction of the stacked body. The second semiconductor part extends in the stacked body in the stacking direction and a first direction crossing the stacking direction. The third semiconductor part extends in the underlayer in a second direction connecting the first semiconductor part and the second semiconductor part. The second semiconductor part separates the stacked body in the second direction. The first semiconductor part, the second semiconductor part and the third semiconductor part are made of a same material and are continuous with each other. The charge storage film is provided between the first semiconductor part and the electrode layers. The first metal layer is in contact with a side surface of the second semiconductor part.

Hereinafter, embodiments will be described with reference to the drawings. Incidentally, the same components in the respective drawings are denoted by the same reference numerals.

A semiconductor device of an embodiment is a semiconductor memory device including a memory cell array.

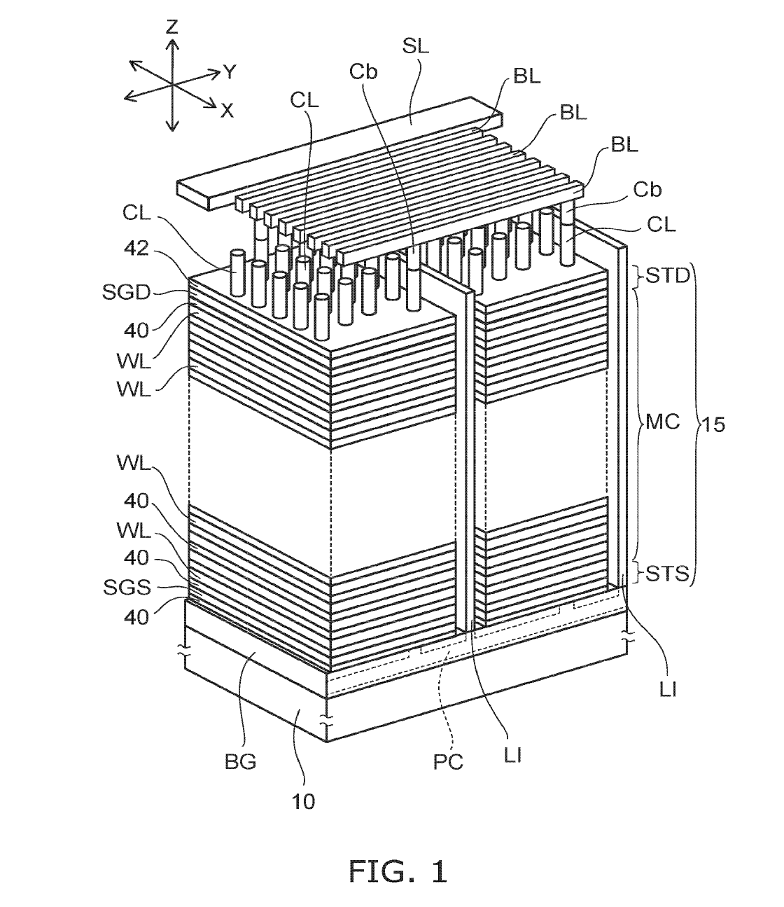

FIG. 1 is a schematic perspective view of a memory cell array 1 of the embodiment.

In FIG. 1, two directions parallel to a major surface of a substrate 10 and perpendicular to each other are an X-direction (first direction) and a Y-direction (second direction), and a direction perpendicular to both the X-direction and the Y-direction is a Z-direction (third direction, stacking direction).

The memory cell array 1 includes a stacked body 15 including a plurality of electrode layers WL, select gate SGS, select gate SGD, a plurality of insulating layers 40, a plurality of columnar parts CL, and a plurality of isolation parts LI.

The columnar part CL is formed into a cylindrical shape or an elliptic cylindrical shape extending in the stacking direction (Z-direction) in the stacked body 15. The isolation part LI extends in the stacking direction (Z-direction) and the X-direction in the stacked body 15, and isolates the stacked body 15 in the Y-direction.

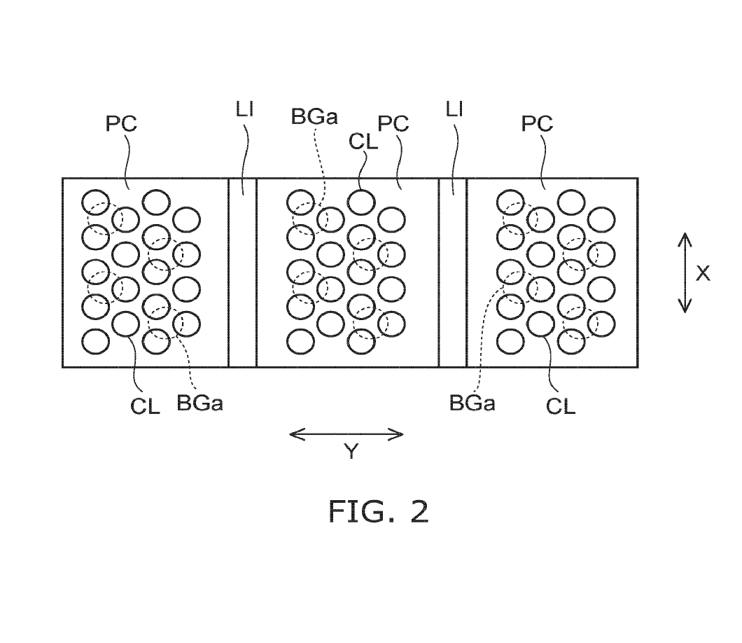

FIG. 2 is a schematic plan view showing an arrangement example of the columnar parts CL and the isolation parts LI.

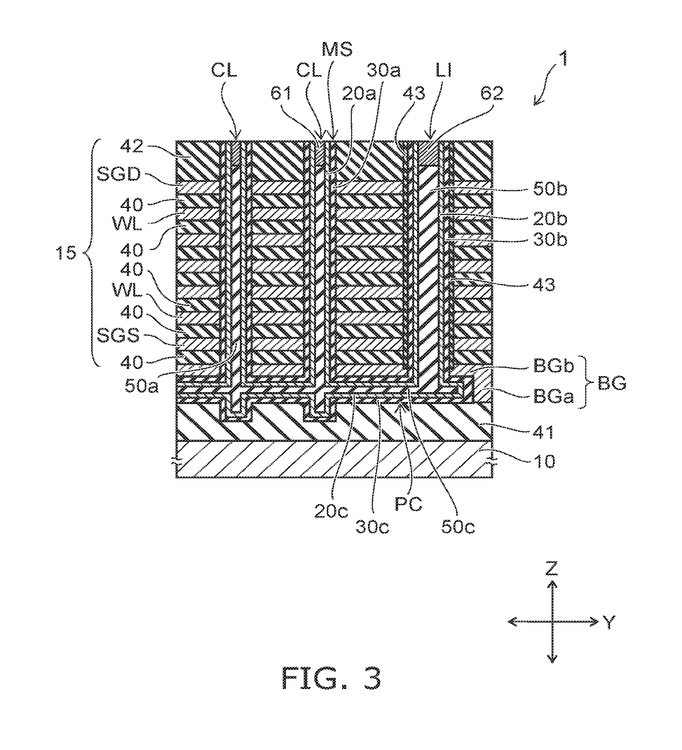

FIG. 3 is a schematic sectional view of the memory cell array 1. FIG. 3 corresponds to a section parallel to a Y-Z plane in FIG. 1. FIG. 3 shows, for example, one columnar part CL and one isolation part LI.

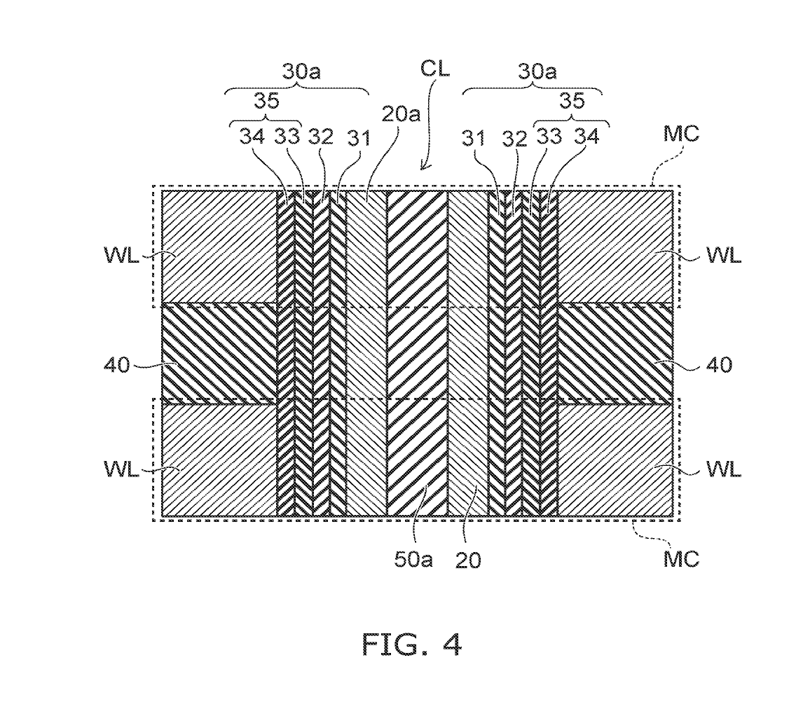

FIG. 4 is an enlarged sectional view of a part of FIG. 3.

An underlayer is provided on the substrate 10 via an insulating layer 41. The underlayer includes a back gate BG provided between the third semiconductor part 20c and the stacked body 15.

As shown in FIG. 3, the back gate BG is provided on the substrate 10 via an insulating layer 41. The back gate BG is a conductive layer. For example, the back gate BG is a silicon layer containing silicon as a main component, and the silicon layer is doped with an impurity (for example, boron) for giving conductivity.

The source side select gate (lower gate layer) SGS is provided on the back gate BG via the insulating layer 40.

The stacked body including the electrode layers WL and the insulating layers 40 is provided on the source side select gate SGS. The stacked body includes the electrode layers WL stacked in the Z-direction via insulators. Although the insulators are, for example, the insulating layers 40, they may be air gaps. The electrode layers WL and the insulating layers 40 are alternately stacked in the Z-direction.

The drain side select gate (upper gate layer) SGD is provided on the uppermost electrode layer WL via the insulating layer 40. An insulating layer 42 is provided on the drain side select gate SGD.

The source side select gate SGS, the drain side select gate SGD and the electrode layers WL are metal layers. For example, the source side select gate SGS, the drain side select gate SGD and the electrode layers WL contain tungsten or molybdenum as a main component. Alternatively, the source side select gate SGS, the drain side select gate SGD and the electrode layers WL are silicon layers containing silicon as a main component, and the silicon layers are doped with, for example, boron as an impurity for giving conductivity. The silicon layers may contain metal silicide.

In the example shown in FIGS. 1 and 2, the columnar parts CL are arranged in, for example, houndstooth check pattern. Alternatively, the columnar parts CL may be arranged in square lattice form along the X-direction and the Y-direction.

A plurality of bit lines (for example, metal films) BL are provided on the stacked body 15. The bit lines BL are separated from each other in the X-direction. Each bit line BL extends in the Y-direction.

An upper end part of the columnar part CL is connected to the bit line BL via a contact part Cb shown in FIG. 1. A columnar parts group, which includes a plurality of columnar parts CL respectively selected from respective areas separated in the Y-direction by the isolation parts LI, are connected to one common bit line BL.

As shown in FIG. 1, a connecting part PC is provided in the back gate BG. A lower end of the columnar part CL and a lower end of the isolation part LI reach the connecting part PC.

As shown in FIG. 3, the columnar part CL includes a first semiconductor part 20a, a memory film 30a and a core insulating film 50a. The isolation part LI includes a second semiconductor part 20b, an insulating film 30b and a core insulating film 50b. The connecting part PC includes a third semiconductor part 20c, an insulating film 30c and a core insulating film 50c.

The first semiconductor part 20a, the second semiconductor part 20b and the third semiconductor part 20c are semiconductor films made of the same material, and continuously provided in the columnar part CL, the isolation part LI and the connecting part PC. The first semiconductor part 20a, the second semiconductor part 20b and the third semiconductor part 20c are, for example, silicon films.

One second semiconductor part 20b is connected to a plurality of first semiconductor parts 20a.

Impurity concentrations of the first semiconductor part 20a, the second semiconductor part 20b and the third semiconductor part 20c are substantially equal to each other. When the impurity concentrations are different from each other, the first semiconductor part 20a, the second semiconductor part 20b and the third semiconductor part 20c are semiconductor films of the same material.

The first semiconductor part 20a, the second semiconductor part 20b and the third semiconductor part 20c are continuously integrally provided. A film of a material different from the first semiconductor part 20a, the second semiconductor part 20b and the third semiconductor part 20c, such as an oxide film, does not intervene between the first semiconductor part 20a and the third semiconductor part 20c, and between the second semiconductor part 20b and the third semiconductor part 20c.

The memory film 30a, the insulating film 30b and the insulating film 30c are insulating films made of the same material, and continuously provided in the columnar part CL, the isolation part LI and the connecting part PC.

The core insulating film 50a, the core insulating film 50b and the core insulating film 50c are insulating films made of the same material, and continuously provided in the columnar part CL, the isolation part LI and the connecting part PC.

The pipe-shaped first semiconductor part 20a and the pipe-shaped memory film 30a extend in the Z-direction in the stacked body 15. The memory film 30a is provided between the stacked body 15 and the first semiconductor part 20a, and surrounds the first semiconductor part 20a from the outer peripheral side. The core insulating film 50a is provided inside the first semiconductor part 20a.

As shown in FIG. 4, the memory film 30a includes a block insulating film 35, a charge storage film 32 and a tunnel insulating film 31.

The block insulating film 35, the charge storage film 32 and the tunnel insulating film 31 are provided in sequence from the electrode layer WL side between the electrode layer WL and the first semiconductor part 20a. The block insulating film 35 contacts the electrode layer WL, and the tunnel insulating film 31 contacts the first semiconductor part 20a. The charge storage film 32 is provided between the block insulating film 35 and the tunnel insulating film 31.

FIG. 4 shows, for example, two memory cells MC. The memory cell MC has a vertical transistor structure in which the electrode layer WL surrounds the periphery of the first semiconductor part 20a via the memory film 30a.

The first semiconductor part 20a functions as a channel, and the electrode layer WL functions as a control gate. The charge storage film 32 functions as a data storage layer to store charge injected from the first semiconductor part 20a.

The semiconductor memory device of the embodiment is a nonvolatile semiconductor memory device which can freely erase and write data electrically, and can hold memory contents even when the power supply is turned off.

The memory cell MC is, for example, a charge-trap type memory cell. The charge storage film 32 includes many trap sites for trapping charge, and includes, for example, a silicon nitride film.

The tunnel insulating film 31 become a potential barrier when charge is injected into the charge storage film 32 from the first semiconductor part 20a or when charge stored in the charge storage film 32 diffuses into the first semiconductor part 20a. The tunnel insulating film 31 includes, for example, a silicon oxide film. Alternatively, the tunnel insulating film 31 includes a stacked film (ONO film) having a structure in which a silicon nitride film is interposed between a pair of silicon oxide films. The tunnel insulating film 31 including the ONO film enables an erasing operation in low electric field as compared with the single layer of the silicon oxide film.

The block insulating film 35 prevents charge stored in the charge storage film 32 from diffusing into the electrode layer WL. The block insulating film 35 includes a cap film 34 provided in contact with the electrode layer WL and a block film 33 provided between the cap film 34 and the charge storage film 32.

The block film 33 is, for example, a silicon oxide film. The cap film 34 has a dielectric constant higher than that of the silicon oxide film. The cap film 34 is, for example, a silicon nitride film, an aluminum oxide film, a hafnium oxide film or an yttrium oxide film. Back tunnel electrons injected from the electrode layer WL at erasing can be suppressed by providing the cap film 34 in contact with the electrode layer WL.

As shown in FIG. 1, a drain side select transistor STD is provided at an upper end part of the columnar part CL, and a source side select transistor STS is provided at a lower end part.

The memory cell MC, the drain side select transistor STD and the source side select transistor STS are vertical transistor in which current flows in the stacking direction (Z-direction) of the stacked body 15.

The drain side select gate SGD functions as a gate electrode (control gate) of the drain side select transistor STD. An insulating film functioning as a gate insulating film of the drain side select transistor STD is provided between the drain side select gate SGD and the first semiconductor part 20a.

The source side select gate SGS functions as a gate electrode (control gate) of the source side select transistor STS. An insulating film functioning as a gate insulating film of the source side select transistor STS is provided between the source side select gate SGS and the first semiconductor part 20a.

A plurality of memory cells MC, each of which includes the electrode layer WL as the control gate, are provided between the drain side select transistor STD and the source side select transistor STS. The plurality of memory cells MC, the drain side select transistor STD and the source side select transistor STS are connected in series via the first semiconductor part 20a, and constitute one memory string. A plurality of the memory strings are arranged in the X-direction and the Y-direction. The plurality of memory cells MC are three-dimensionally provided in the X-direction, the Y-direction and the Z-direction.

Next, the isolation part LI will be described.

As shown in FIG. 3, the isolation part LI includes the second semiconductor part 20b, the insulating film 30b, an insulating film 43 and the core insulating film 50b.

The core insulating film 50b spreads in the Z-direction and in a depth direction penetrating through a plane of paper in FIG. 3 (corresponding to the X-direction in FIG. 1). The second semiconductor part 20b, the insulating film 30b and the insulating film 43 are provided in sequence from the core insulating film 50b side at both side walls of the core insulating film 50b in the Y-direction. A stacked film including the insulating film 43, the insulating film 30b and the second semiconductor part 20b is provided between the stacked body 15 and the core insulating film 50b. The stacked film spreads planarly in the Z-direction and the X-direction. The insulating film 43 is provided between the stacked body 15 and the insulating film 30b. The insulating film 30b is provided between the insulating film 43 and the second semiconductor part 20b. The second semiconductor part 20b is provided between the insulating film 30b and the core insulating film 50b.

Next, the connecting part PC will be described.

The connecting part PC is provided in the back gate BG under the stacked body 15. The connecting part PC includes the third semiconductor part 20c, the insulating film 30c and the core insulating film 50c.

An upper layer part BGb of the back gate BG is provided between the connecting part PC and the stacked body 15. A stacked film of the third semiconductor part 20c and the insulating film 30c is provided between the core insulating film 50c and the upper layer part BGb of the back gate BG. The insulating film 30c is provided between the upper layer part BGb of the back gate BG and the third semiconductor part 20c.

The stacked film of the third semiconductor part 20c and the insulating film 30c is provided also on the lower side of the core insulating film 50c. The stacked film of the third semiconductor part 20c and the insulating film 30c is provided between the core insulating film 50c and the insulating layer 41. The insulating film 30c is provided between the third semiconductor part 20c and the insulating layer 41.

The stacked film of the third semiconductor part 20c and the insulating film 30c, which is provided on the upper and lower sides of the core insulating film 50c, spreads planarly in the Y-direction as the direction of connecting the columnar part CL and the isolation part LI, and in the X-direction as the depth direction in FIG. 3.

The connecting part PC, which includes the third semiconductor part 20c, the insulating film 30c and the core insulating film 50c, spreads in a plane parallel to the X-Y plane as shown in FIG. 2. Lower ends of the columnar parts CL and lower ends of the isolation parts LI reach the planarly spreading connecting part PC. The isolation part LI extends in the X-direction in plan view of FIG. 2, and separates the stacked body 15 in the Y-direction.

The back gate BG includes a portion BGa left in a columnar shape between the stacked body 15 and the insulating layer 41 (shown in FIG. 3). The portion BGa is indicated by a broken line in FIG. 2.

Next, an upper structure of the columnar part CL and the isolation part LI will be described.

As shown in FIG. 3, an upper end of the core insulating film 50a of the columnar part CL is retreated downward from an upper end of the first semiconductor part 20a. A metal layer (second metal layer) 61 is provided over the upper end of the retreated core insulating film 50a and inside the first semiconductor part 20a. The metal layer 61 is provided above the drain side select gate SGD and inside the pipe-shaped first semiconductor part 20a. The metal layer 61 is in ohmic contact with the inner peripheral wall of the upper part of the first semiconductor part 20a. The metal layer 61 contains, for example, tungsten, titanium nitride or silicon doped with phosphorus or boron.

A lower end of the metal layer 61 is positioned above the drain side select gate SGD, and the metal layer 61 is not provided in an area facing the drain side select gate SGD. Thus, the metal layer 61 does not influence the threshold of the select transistor STD.

The metal layer 61 is connected to the bit line BL shown in FIG. 1. The first semiconductor part 20a of the columnar part CL is electrically connected to the bit line BL via the metal layer 61.

An upper end of the core insulating film 50b of the isolation part LI is retreated downward from an upper end of the second semiconductor part 20b. A metal layer (first metal layer) 62 is provided over the upper end of the retreated core insulating film 50b and inside the second semiconductor part 20b. The metal layer 62 is provided above the drain side select gate SGD and inside the pipe-shaped second semiconductor part 20b. The metal layer 62 is in ohmic contact with the inner peripheral wall of the upper part of the second semiconductor part 20b. The metal layer 62 contains, for example, tungsten, titanium nitride, or silicon doped with phosphorus or boron. The metal layer 62 is connected to a not-shown upper interconnect layer (source layer) provided above the stacked body 15. The second semiconductor part 20b of the isolation part LI is electrically connected to the source layer via the metal layer 62.

Next, an operation method will be described.

As described above, the first semiconductor part 20a of the columnar part CL, the second semiconductor part 20b of the isolation part LI and the third semiconductor part 20c of the connecting part PC are the continuous semiconductor films of the same material. Accordingly, current can be made to flow between the bit line and the source layer via the integrated semiconductor films (the first semiconductor part 20a, the second semiconductor part 20b and the third semiconductor part 20c).

At the time of data read-out operation, a read-out judging voltage Vrcg is applied to the electrode layer WL of a selected cell as a read-out object. The selected cell to which the read-out judging voltage Vrcg is applied is turned on or off according to the threshold depending on written data (charge stored in the charge storage film 32).

A read-out voltage Vread is applied to the electrode layer WL of a non-selected cell so that the cell is turned on even if data is written.

Data is not written in the insulating film 30b of the isolation part LI and the insulating film 30c of the connecting part PC, and the second semiconductor part 20b of the isolation part LI and the third semiconductor part 20c of the connecting part PC are normally on.

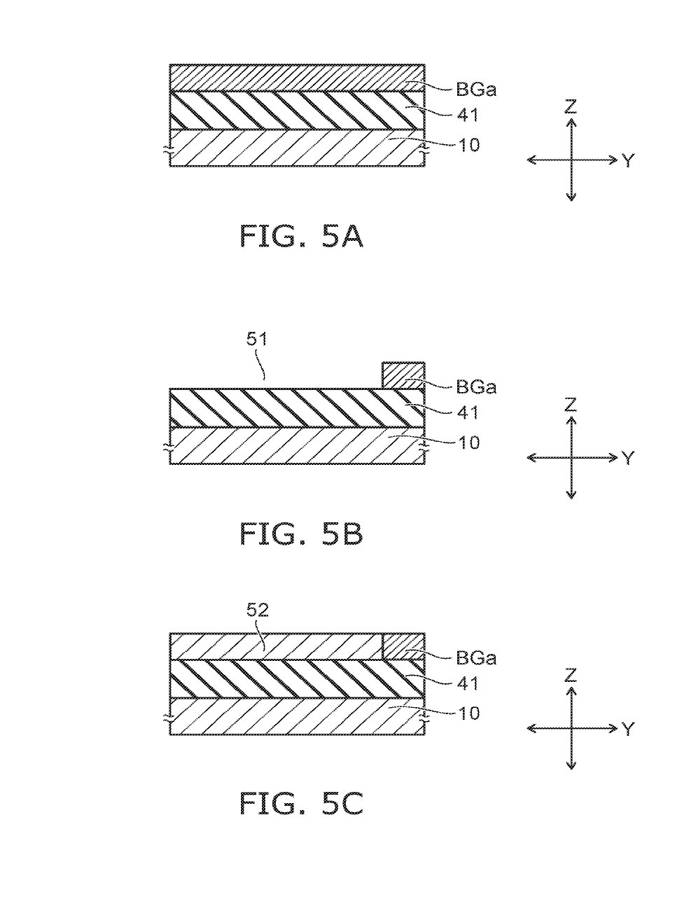

Next, a method for manufacturing the semiconductor memory device of the embodiment will be described with reference to FIG. 5A to FIG. 11.

As shown in FIG. 5A, the conductive layer BGa is formed on the substrate 10 via the insulating layer 41. The substrate 10 is, for example, a semiconductor substrate and is a silicon substrate. The conductive layer BGa is, for example, a silicon layer doped with an impurity such as boron.

As shown in FIG. 5B, a cavity (or recess) 51 is formed in the conductive layer BGa. As shown in FIG. 5C, a sacrifice layer 52 is buried in the cavity 51. The sacrifice layer 52 is, for example, an amorphous silicon film.

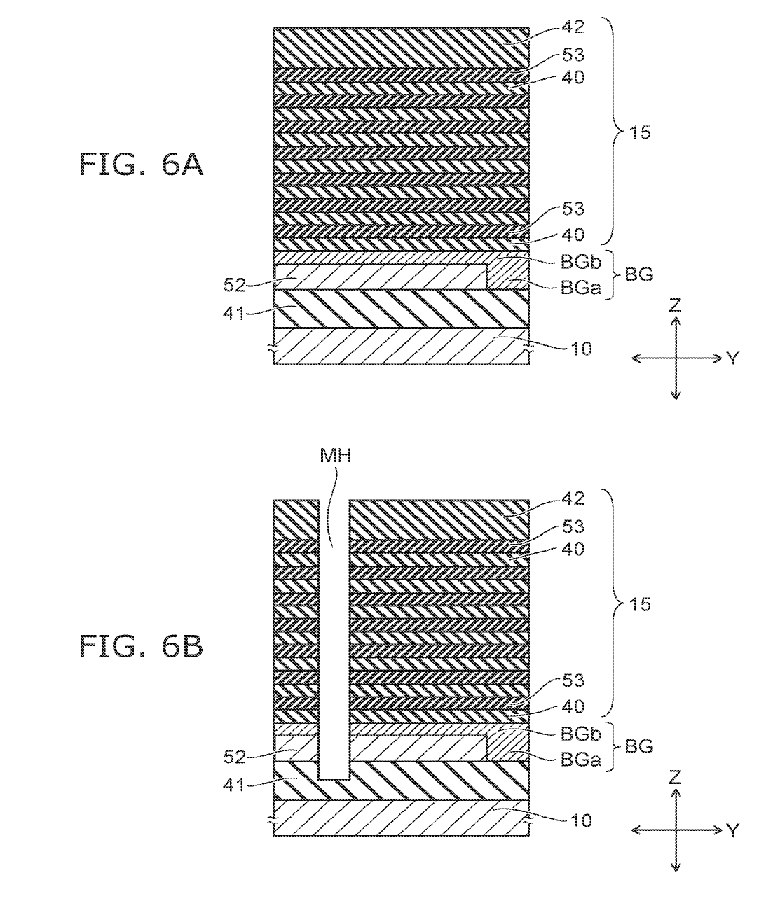

As shown in FIG. 6A, the conductive layer BGb is formed on the conductive layer BGa and the sacrifice layer 52. The sacrifice layer 52 is covered with the conductive layer BGb. The conductive layer BGb is made of the same material as that of the conductive layer BGa, and the conductive layer BGa and the conductive layer BGb constitute the back gate BG described before.

As shown in FIG. 6A, the stacked body 15 including a plurality of first layers 53 and a plurality of second layers 40 is formed on the back gate BG. The second layers 40 and the first layers 53 are alternately stacked on the back gate BG. The process of alternately forming the first layer 53 and the second layer 40 is repeated plural times.

The second layer 40 is an insulating layer between the electrode layers WL, and is, for example, a silicon oxide film. The first layer 53 is made of a material different from that of the second layer 40 and is, for example, a silicon nitride film. The first layer 53 is replaced by the electrode layer WL in a later process.

The stacked body 15 includes the insulating layer 42 formed in the uppermost layer. The insulating layer 42 is, for example, a silicon oxide film.

As shown in FIG. 6B, a memory hole MH is formed in the stacked body 15. The memory hole MH is formed by a reactive ion etching (RIE) method using a not-shown mask layer formed on the stacked body 15.

Although FIG. 6B shows only one memory hole MH, a plurality of memory holes MH are formed in the stacked body 15. An arrangement example of the memory holes MH corresponds to the arrangement example of the columnar parts CL shown in FIG. 2.

The memory hole MH passes through the stacked body 15 and reaches the sacrifice layer 52. The memory hole MH may pass through the sacrifice layer 52 or may stop at the sacrifice layer 52.

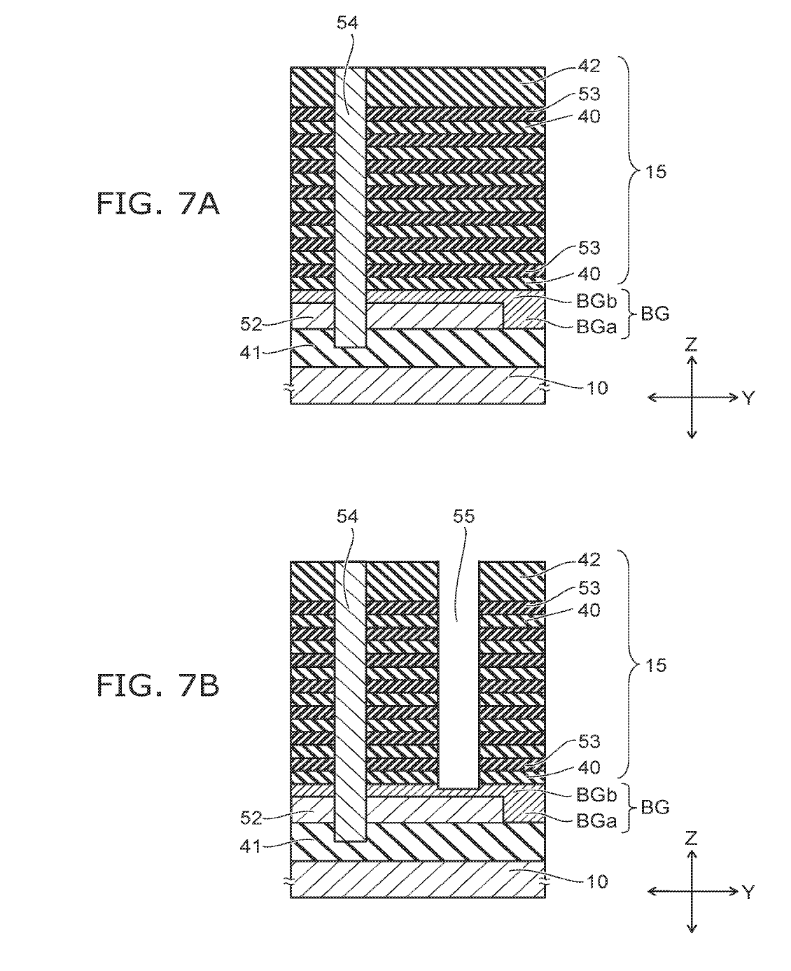

As shown in FIG. 7A, a sacrifice film 54 is buried in the memory hole MH. The sacrifice film 54 is made of a similar material to that of the sacrifice layer 52 and is, for example, an amorphous silicon film.

Next, as shown in FIG. 7B, a trench 55 is formed in the stacked body 15. The trench 55 is formed by the RIE method using a not-shown mask layer formed on the stacked body 15. The trench 55 extends in a depth direction penetrating through a plane of paper in FIG. 7B.

Although FIG. 7B shows only one trench 55, a plurality of trenches 55 are formed in the stacked body 15. An arrangement example of the trenches 55 corresponds to the arrangement example of the isolation parts LI shown in FIG. 2.

The trench 55 passes through the stacked body 15 and reaches the back gate BG. The trench 55 does not reach the sacrifice layer 52.

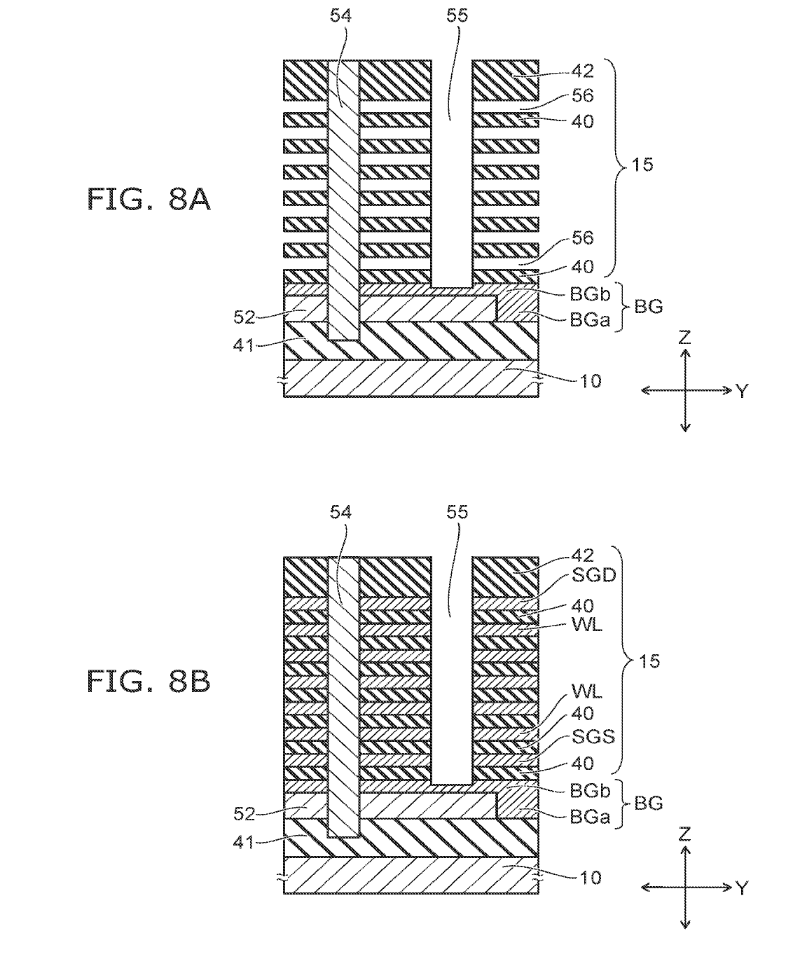

Next, the first layers 53 are removed by etching through the trench 55. For example, the first layers 53 are removed by wet etching using a chemical solution. As shown in FIG. 8A, spaces 56 are formed in the stacked body 15 by the removal of the first layers 53. The space 56 is formed between the second layers 40. The space 56 is formed between the insulating layer 42 and the uppermost second layer 40.

Conductive layers which become the select gate SGS, the select gate SGD and the electrode layers WL are buried in the spaces 56 through the trench 55. The conductive layers are metal layers and contain, for example, tungsten or molybdenum. As shown in FIG. 8B, the source side select gate SGS, the electrode layers WL and the drain side select gate SGD are stacked in order from the lower layer side via the insulating layers 40.

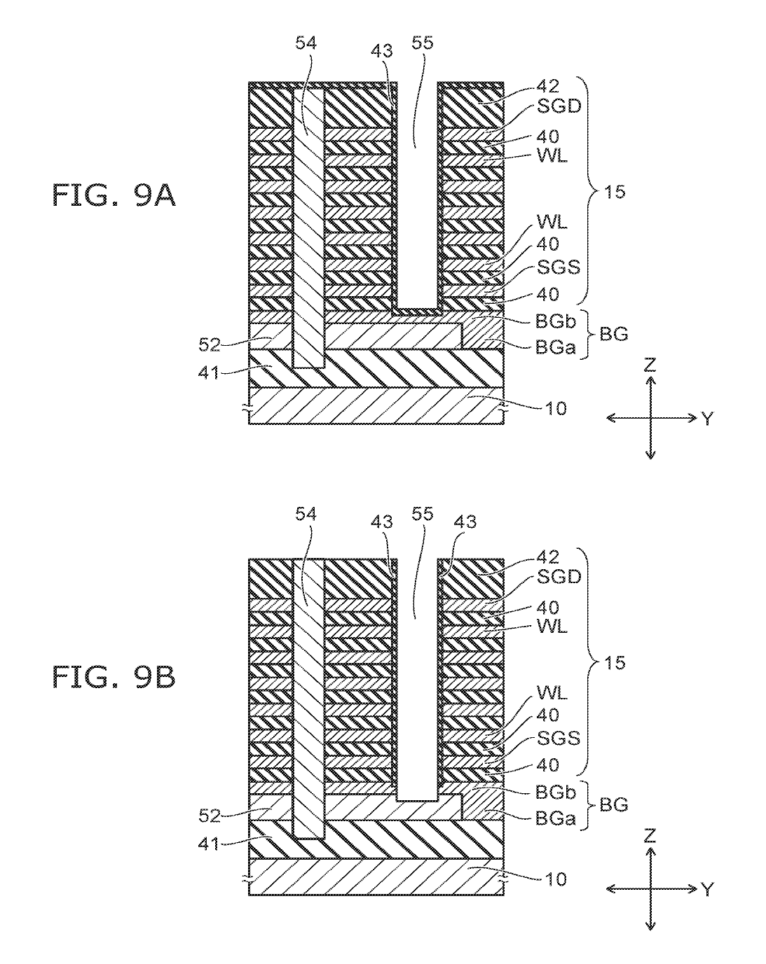

As shown in FIG. 9A, the insulating film 43 is formed in the trench 55. The insulating film 43 is conformally formed on the bottom and side wall of the trench 55. Besides, the insulating film 43 is deposited also on the upper surface of the stacked body 15.

The insulating film 43 on the bottom of the trench 55 is removed by, for example, the RIE method. The insulating film 43 deposited on the upper surface of the stacked body 15 is also removed. The back gate BG is exposed at the bottom of the trench 55 by the removal of the insulating film 43 on the bottom of the trench 55. The back gate BG at the bottom of the trench 55 is removed by, for example, the RIE method. As shown in FIG. 9B, the sacrifice layer 52 is exposed at the bottom of the trench 55 by the removal of the back gate BG at the bottom of the trench 55.

The sacrifice layer 52 is removed by etching through the trench 55. At this time, the sacrifice film 54 made of the same material as that of the sacrifice layer 52, which is, for example, amorphous silicon, is also removed. For example, the sacrifice layer 52 and the sacrifice film 54 are moved by wet etching using a chemical solution. After the sacrifice film 54 is removed, the sacrifice layer 52 is etched also through the memory hole MH.

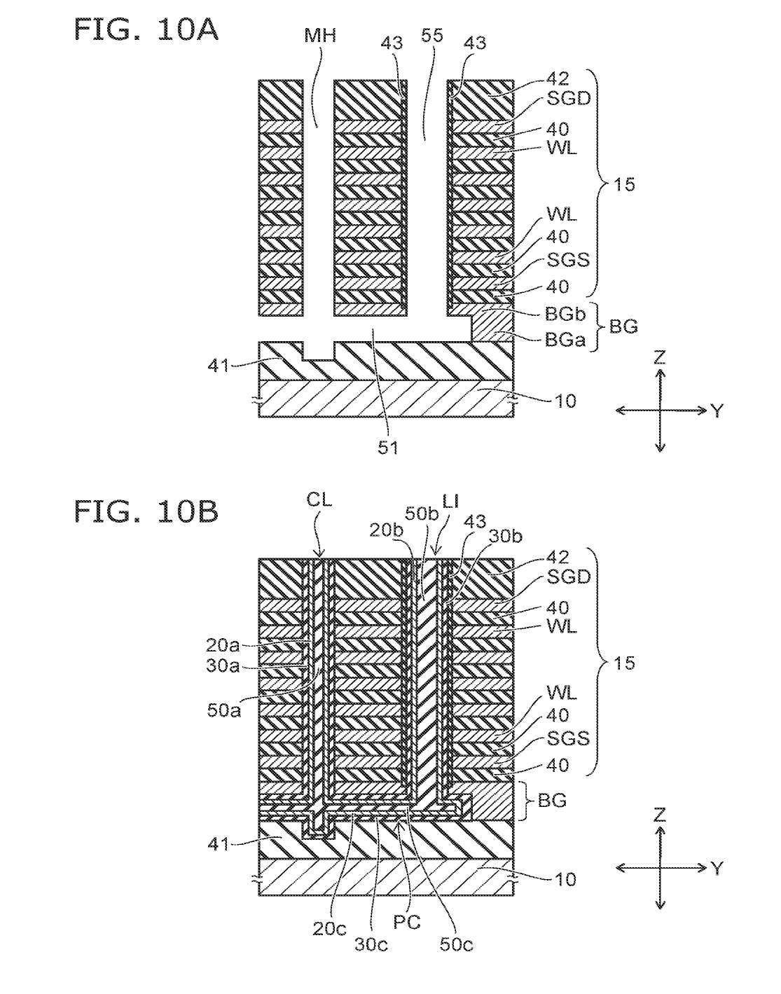

As shown in FIG. 10A, the cavity 51 appears by the removal of the sacrifice layer 52. The memory hole MH appears by the removal of the sacrifice film 54. The memory hole MH, the cavity 51 and the trench 55 are continuously connected to each other.

Even if the cavity 51 exists between the stacked body 15 and the insulating layer 41, the part BGa (shown also in FIG. 2) of the back gate BG remaining in the columnar shape between the stacked body 15 and the insulating layer 41 supports the stacked body 15.

As shown in FIG. 10B, the memory film 30a is formed on the side wall of the memory hole MH, and the insulating film 30c is formed on the inner wall of the cavity 51. The insulating film 30b is formed on the side wall of the trench 55 via the insulating film 43. The memory film 30a, the insulating film 30c and the insulating film 30b are integrally formed as the continuous film made of the same material and having the same stacked film structure.

The first semiconductor part 20a is formed inside the memory film 30a in the memory hole MH. The third semiconductor part 20c is formed inside the insulating film 30c in the cavity 51. The second semiconductor part 20b is formed inside the insulating film 30b in the trench 55. The first semiconductor part 20a, the third semiconductor part 20c and the second semiconductor part 20b are integrally formed as the continuous semiconductor film (for example, silicon film) of the same material.

The core insulating film 50a is formed inside the first semiconductor part 20a in the memory hole MH. The core insulating film 50c is formed inside the third semiconductor part 20c in the cavity 51. The core insulating film 50b is formed inside the second semiconductor part 20b in the trench 55. The core insulating film 50a, the core insulating film 50c and the core insulating film 50b are integrally formed as the continuous insulating film (for example, silicon nitride film) of the same material.

The memory film 30a, the first semiconductor part 20a and the core insulating film 50a form the columnar part CL. The insulating film 30b, the second semiconductor part 20b and the core insulating film 50b form the isolation part LI. The insulating film 30c, the third semiconductor part 20c and the core insulating film 50c form the connecting part PC.

Next, the core insulating film 50a and the core insulating film 50b are etched back by, for example, the RIE method, so that the upper surface of the core insulating film 50a and the upper surface of the core insulating film 50b are simultaneously retreated.

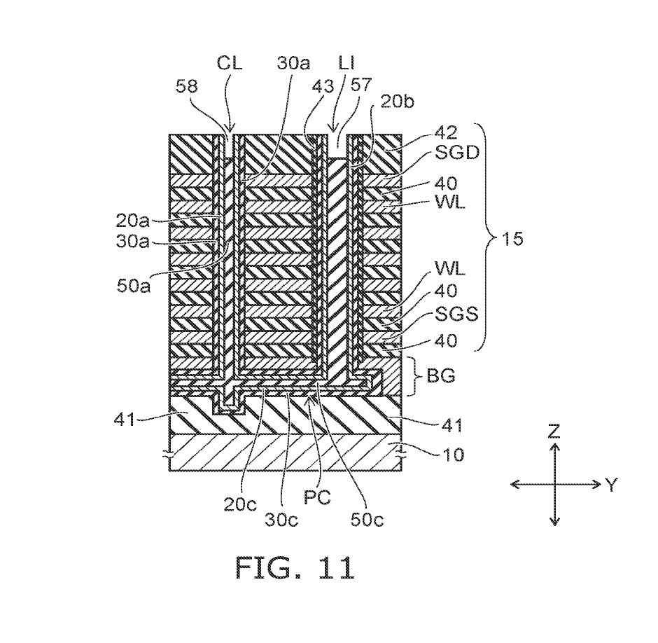

As shown in FIG. 11, the upper surface of the core insulating film 50a and the upper surface of the core insulating film 50b after etch-back are located above the drain side select gate SGD. A recess 58 is formed on the core insulating film 50a of the columnar part CL, and the upper inner side wall of the first semiconductor part 20a is exposed. A recess 57 is formed on the core insulating film 50b of the isolation part LI and the upper inner side wall of the second semiconductor part 20b is exposed.

As shown in FIG. 3, the second metal layer 61 is buried in the recess 58, and the first metal layer 62 is buried in the recess 57. The second metal layer 61 contacts the upper inner side wall of the first semiconductor part 20a, and the first metal layer 62 contacts the upper inner side wall of the second semiconductor part 20b.

Other than the method of the embodiment described above, for example, the columnar part CL and the connecting part PC are formed prior to the isolation part LI, and then, a trench reaching the semiconductor film formed on the inner wall of the upper side of the connecting part PC is formed in the stacked body 15, and a metal material is buried in the trench, so that the semiconductor film (channel) of the columnar part CL can be connected to the upper interconnect layer (source layer). In this case, a contact area between the semiconductor film of the connecting part PC and the metal layer in the isolation part LI becomes a bottom area of the metal layer.

On the other hand, according to the embodiment, the metal layer 62 contacts the side walls facing to each other in the Y-direction of the second semiconductor part 20b. The second semiconductor part 20b is connected to the first semiconductor part 20a of the columnar part CL. This can make the contact area between the semiconductor film and the metal layer larger than that in the structure in which the bottom of the metal layer buried in the isolation part LI contacts the upper surface of the semiconductor film of the connecting part PC. The enlargement of the contact area reduces the contact resistance between the second semiconductor part 20b and the metal layer 62, and reduces the electrical resistance between the first semiconductor part 20a of the columnar part CL and the upper interconnect layer (source layer).

Besides, according to the embodiment, after the first layers 53 are replaced by the electrode layers WL, the memory film 30a is formed in the memory hole MH. When the first layers 53 are removed by, for example, a chemical solution, the sacrifice film 54 is buried in the memory hole MH and the memory film 30a is not formed. Thus, the block film on the outermost peripheral side of the memory film 30 is not etched at etching for removing the first layers 53, and there is no influence by that on device characteristics.

Next, another embodiment will be described.

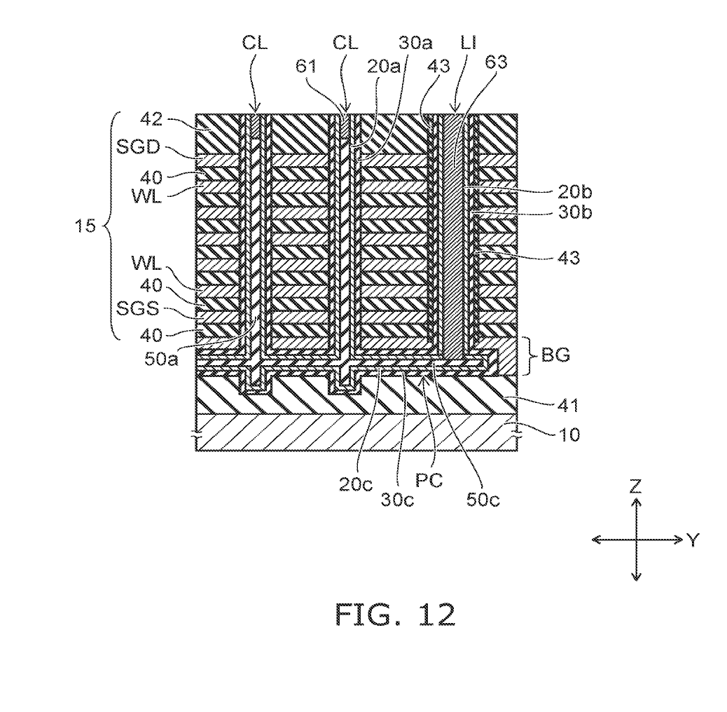

FIG. 12 is a schematic sectional view of a memory cell array of another embodiment and is similar to FIG. 3. The detailed description of the same components as those of the embodiment shown in FIG. 3 is omitted.

A first metal layer 63 is provided inside a second semiconductor part 20b of the isolation part LI. The first metal layer 63 contains, for example, tungsten or molybdenum as a main component. The first metal layer 63 spreads in the Z-direction and a depth direction penetrating through a plane of paper (X-direction), and separates a stacked body 15 in a Y-direction. A lower end of the first metal layer 63 contacts a third semiconductor part 20c of a connecting part PC.

The second semiconductor part 20b, an insulating film 30b and an insulating film 43 are provided between the stacked body 15 and both side walls of the first metal layer 63 in the Y-direction.

A first semiconductor part 20a of a columnar part CL, the third semiconductor part 20c of the connecting part PC, and the second semiconductor part 20b of the isolation part LI are continuous semiconductor films (for example, silicon films) of the same material similarly to the foregoing embodiment.

However, the second semiconductor part 20b of the isolation part LI contains an impurity (for example, phosphorus, boron, arsenic) having a higher concentration than that of the first semiconductor part 20a and the third semiconductor part 20c. The impurity concentration (carrier concentration) of the second semiconductor part 20b is higher than the impurity concentration (carrier concentration) of the first semiconductor part 20a and the impurity concentration (carrier concentration) of the third semiconductor part 20c. The resistance of the second semiconductor part 20b is lower than the resistance of the first semiconductor part 20a and the resistance of the third semiconductor part 20c.

The second semiconductor part 20b contacts the side wall of the first metal layer 63. The impurity concentration (carrier concentration) of a portion of the second semiconductor part 20b, which the first metal layer 63 contacts, is higher than the impurity concentration (carrier concentration) of the first semiconductor part 20a and the impurity concentration (carrier concentration) of the third semiconductor part 20c.

Next, a method for manufacturing the semiconductor memory device shown in FIG. 12 will be described.

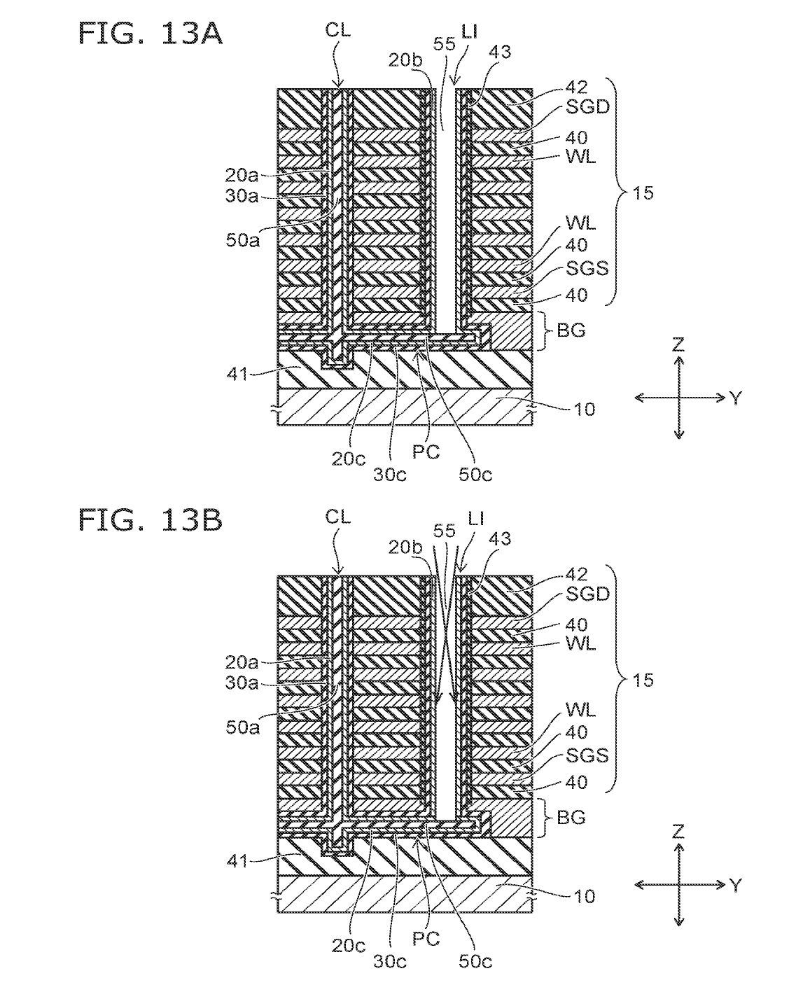

Processes up to FIG. 10B proceed similarly to the foregoing embodiment. Thereafter, in a state where the columnar part CL is covered with a mask, a core insulating film 50b of the isolation part LI is removed by, for example, an RIE method. As shown in FIG. 13A, a trench 55 appears inside the second semiconductor part 20b of the isolation part LI.

The second semiconductor part 20b is exposed in the trench 55. An impurity (phosphorus, boron, arsenic, etc.) is introduced into the exposed second semiconductor part 20b by, for example, an ion implantation method as schematically indicated by an arrow in FIG. 13B. The impurity introduced in the second semiconductor part 20b diffuses into the second semiconductor part 20b by a subsequent heat treatment. Incidentally, the heat treatment may not be performed immediately after the ion implantation.

An impurity is not intentionally introduced into the first semiconductor part 20a of the columnar part CL and the third semiconductor part 20c of the connecting part PC. Accordingly, the impurity concentration of the second semiconductor part 20b is higher than the impurity concentration of the first semiconductor part 20a and the impurity concentration of the third semiconductor part 20c. Thereafter, the first metal layer 63 is buried in the trench 55 as shown in FIG. 12.

According to the embodiment shown in FIG. 12, the first metal layer 63 contacts the side walls facing to each other in the Y-direction, of the second semiconductor part 20b. The second semiconductor part 20b is connected to the first semiconductor part 20a of the columnar part CL. This can make the contact area between the semiconductor film and the metal layer larger than that in the structure in which the bottom of the metal layer buried in the isolation part LI contacts the upper surface of the semiconductor film of the connecting part PC.

The enlargement of the contact area reduces the contact resistance between the second semiconductor part 20b and the first metal layer 63, and reduces the electrical resistance between the first semiconductor part 20a of the columnar part CL and the upper interconnect layer (source layer). Besides, since the impurity concentration of the second semiconductor part 20b is made high, the contact resistance between the first metal layer 63 and the second semiconductor part 20b is reduced.

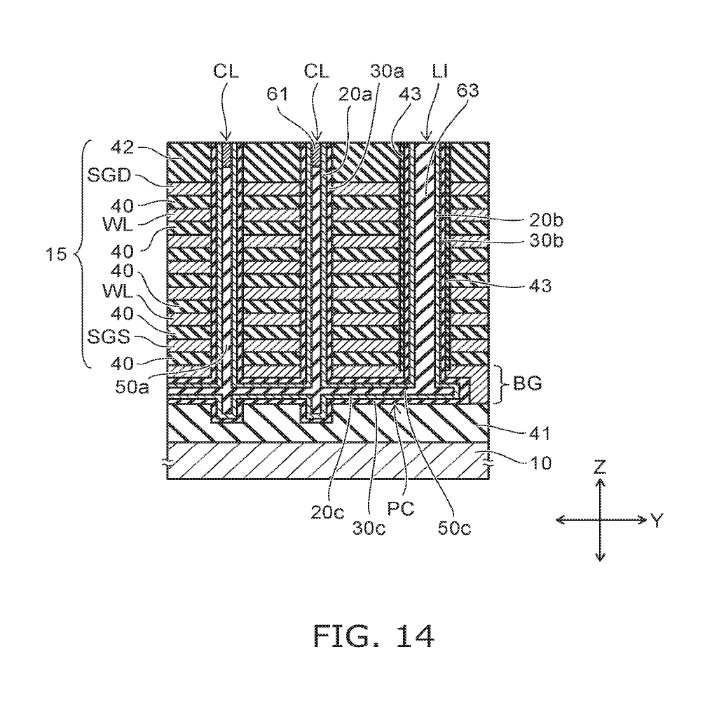

As shown in FIG. 14, the first metal layer 63 in the isolation part LI may not reach the connecting part PC. Besides, even if the impurity concentration of the second semiconductor part 20b which the first metal layer 63 contacts is equal to the impurity concentration of the first semiconductor part 20a, the contact area between the metal layer and the second semiconductor part 20b can be made large as compared with the embodiment shown in FIG. 3, and the contact resistance between the metal layer and the second semiconductor part 20b can be reduced.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device comprising:
an underlayer;
a stacked body provided on the underlayer and including a plurality of electrode layers stacked with insulators between the electrode layers;
a semiconductor film including a first semiconductor part extending in the stacked body in a stacking direction of the stacked body, a second semiconductor part extending in the stacked body in the stacking direction and a first direction crossing the stacking direction, and a third semiconductor part extending in the underlayer in a second direction connecting the first semiconductor part and the second semiconductor part, the second semiconductor part separating the stacked body in the second direction, the first semiconductor part, the second semiconductor part and the third semiconductor part being made of a same material and being continuous with each other;
a charge storage film provided between the first semiconductor part and the electrode layers; and
a first metal layer in contact with a side surface of the second semiconductor part.

2. The device according to claim 1, wherein one second semiconductor part is connected to a plurality of first semiconductor parts.

3. The device according to claim 1, wherein an impurity concentration of the second semiconductor part is higher than an impurity concentration of the first semiconductor part.

4. The device according to claim 1, wherein an impurity concentration of the second semiconductor part is higher than an impurity concentration of the third semiconductor part.

5. The device according to claim 1, wherein the first metal layer separates the stacked body in the second direction.

6. The device according to claim 5, wherein a lower end of the first metal layer contacts the third semiconductor part.

7. The device according to claim 1, wherein
the second semiconductor part includes a portion contacting the first metal layer,
an impurity concentration of the portion of the second semiconductor part is higher than an impurity concentration of the first semiconductor part.

8. The device according to claim 1,
wherein the stacked body includes a select gate provided above an uppermost electrode layer, and
further comprising a second metal layer in contact with the first semiconductor part above the select gate.

9. The device according to claim 8, wherein the first metal layer is provided above the select gate.

10. The device according to claim 1, wherein the underlayer includes a back gate provided between the third semiconductor part and the stacked body.

11. The device according to claim 1, wherein the third semiconductor part spreads in a planar shape in the first direction and the second direction.

12. The device according to claim 1, wherein the second semiconductor part spreads in a planar shape in the stacking direction and the first direction.

13. The device according to claim 1, wherein a film of a same material as the charge storage film is provided between the third semiconductor part and the stacked body, and between the second semiconductor part and the stacked body.

14. The device according to claim 1, further comprising a core insulating film of a same material continuously provided inside the first semiconductor part, inside the third semiconductor part and inside the second semiconductor part.

15. A method for manufacturing a semiconductor device, comprising:
forming a stacked body on a sacrifice layer, the stacked body including a plurality of first layers and a plurality of second layers alternately stacked;
forming a hole and a trench in the stacked body, the hole extending in a stacking direction of the stacked body and reaching the sacrifice layer, the trench extending in the stacking direction and reaching the sacrifice layer;
removing the sacrifice layer through the trench or the hole, and forming a cavity connected with the trench and the hole under the stacked body;
forming a continuous semiconductor film of a same material on a side wall of the hole, an inner wall of the cavity, and a side wall of the trench with intervening a film including a charge storage film; and
forming a meta layer inside the semiconductor film in the trench, the metal layer being in contact with the semiconductor film.

16. The method according to claim 15, further comprising introducing an impurity into the semiconductor film in the trench and making an impurity concentration of the semiconductor film in the trench higher than an impurity concentration of the semiconductor film in the hole.

17. The method according to claim 15, further comprising burying a sacrifice film in the hole;
replacing the first layer by an electrode layer through the trench in a state where the sacrifice film is buried in the hole; and
removing the sacrifice film in the hole after the first layer is replaced by the electrode layer.

18. The method according to claim 17, wherein
the sacrifice layer under the stacked body and the sacrifice film in the hole are made of a same material, and
when the sacrifice film is removed, the sacrifice layer is also removed to form the cavity.

19. The method according to claim 17, further comprising forming an insulating film on a side wall of the trench after the first layer is replaced by the electrode layer.

20. The method according to claim 15, further comprising:
forming a continuous core insulating film of a same material inside of the semiconductor film in the hole, inside of the semiconductor film in the cavity, and inside of the semiconductor film in the trench, and
etching back a top of the core insulating film in the trench, and exposing a side wall of the semiconductor film in the trench, wherein
the metal layer is formed inside the exposed side wall of the semiconductor film.
